(19) United States
(12) Patent Application Publication
(10) Pub. No.: US 2026/0206452 A1
(43) Pub. Date: Jul. 16, 2026

(54) DISPLAY DEVICE

(71) Applicant: Sharp Display Technology Corporation, Kameyama City, Mie (JP)

(72) Inventors: Takao SAITOH, Kameyama City, Mie (JP); Yohsuke KANZAKI, Kameyama City, Mie (JP); Masaki YAMANAKA, Kameyama City, Mie (JP); Masahiko MIWA, Kameyama City, Mie (JP); Yi SUN, Kameyama City, Mie (JP); Masaki FUJIWARA, Kameyama City, Mie (JP); Kouhei KAMATANI, Kameyama City, Mie (JP)

(21) Appl. No.: 18/866,625

(22) PCT Filed: Jul. 11, 2022
(86) PCT No.: PCT/JP2022/027271

§ 371 Date: Nov. 18, 2024

(51) Int. Cl. H10K 59/35; H10K 59/124

(52) U.S. Cl. CPC H10K 59/353; H10K 59/124

(57) ABSTRACT

A display device includes: a display panel including a display region where a plurality of subpixels are arranged, the display region including a first display region, a second display region provided adjacent to the first display region, and a third display region provided inside the second display region; and an electronic component that is provided on one front face side of the display panel and overlaps with the third display region, wherein the second display region is provided along an edge of the display panel, and a density of the subpixels that can be turned on in the second display region other than the third display region is less than a density of the subpixels that can be turned on in the first display region and greater than a density of the subpixels that can be turned on in the third display region.

### TECHNICAL FIELD

The disclosure relates to a display device.

### BACKGROUND ART

In recent years, as a display device replacing a liquid crystal display device, a self-luminous organic electroluminescence (hereinafter also referred to as “EL”) display device using an organic EL element has attracted attention. For organic EL display devices, a structure has been proposed in which, for example, an image capturing region where an imaging element such as a camera is disposed is provided inside a display region where a plurality of subpixels are arranged.

For example, PTL 1 discloses a display device in which scanning signal lines and data signal lines extending to a display area bypass a light transmission region for image capturing inside the display area.

### CITATION LIST

### Patent Literature

PTL 1: WO 2019/198163 Pamphlet (FIG. 4)

### SUMMARY

### Technical Problem

In an organic EL display device in which an electronic component such as an imaging element is disposed inside a display region, since the subpixels are thinned out in order to use light transmitted through a display panel in the electronic component, a boundary between a region where the subpixels are thinned out and a region where the subpixels are not thinned out is easily visually recognized.

The disclosure has been made in view of the above, and an object of the disclosure is to make a boundary between a region where the subpixels are thinned out and a region where the subpixels are not thinned out hard to visually recognize.

### Solution to Problem

To solve the problems described above, a display device according to the disclosure includes: a display panel including a display region where a plurality of subpixels are arranged, the display region including a first display region, a second display region provided adjacent to the first display region, and a third display region provided inside the second display region; and an electronic component that is provided on one front face side of the display panel and overlaps with the third display region, wherein the second display region is provided along an edge of the display panel, and a density of the subpixels that can be turned on in the second display region other than the third display region is less than a density of the subpixels that can be turned on in the first display region and greater than a density of the subpixels that can be turned on in the third display region.

### Advantageous Effects of Disclosure

According to the disclosure, it is possible to make it difficult to visually recognize a boundary between a region where subpixels are thinned out and a region where the subpixels are not thinned out.

### BRIEF DESCRIPTION OF DRAWINGS

FIG. 1 is a plan view illustrating a schematic configuration of an organic EL display device according to a first embodiment of the disclosure.

FIG. 2 is an enlarged plan view of main portions of a region A in FIG. 1.

FIG. 3 is a plan view of a normal pixel region in a display region of an organic EL display panel constituting the organic EL display device according to the first embodiment of the disclosure.

FIG. 4 is a cross-sectional view of the normal pixel region in the display region of the organic EL display panel taken along a line IV-IV in FIG. 2.

FIG. 5 is a cross-sectional view of a thinned-out pixel region in the display region of the organic EL display panel taken along a line V-V in FIG. 2.

FIG. 6 is an equivalent circuit diagram of a thin film transistor layer constituting the organic EL display panel of the organic EL display device according to the first embodiment of the disclosure.

FIG. 7 is a cross-sectional view of an organic EL layer constituting the organic EL display panel of the organic EL display device according to the first embodiment of the disclosure.

FIG. 8 is a plan view of a modified example of the organic EL display panel constituting the organic EL display device according to the first embodiment of the disclosure.

FIG. 9 is a plan view of an organic EL display panel constituting an organic EL display device according to a second embodiment of the disclosure.

FIG. 10 is an enlarged plan view of main portions of a region C in FIG. 9.

FIG. 11 is a plan view of an organic EL display device according to a third embodiment of the disclosure.

FIG. 12 is a plan view of an organic EL display panel constituting an organic EL display device according to a fourth embodiment of the disclosure.

FIG. 13 is a cross-sectional view of the thinned-out pixel region of the organic EL display panel taken along a line XIII-XIII in FIG. 12.

### DESCRIPTION OF EMBODIMENTS

Embodiments of a technique according to the disclosure will be described below in detail with reference to the drawings. Note that the technique according to the disclosure is not limited to the embodiments to be described below.

### First Embodiment

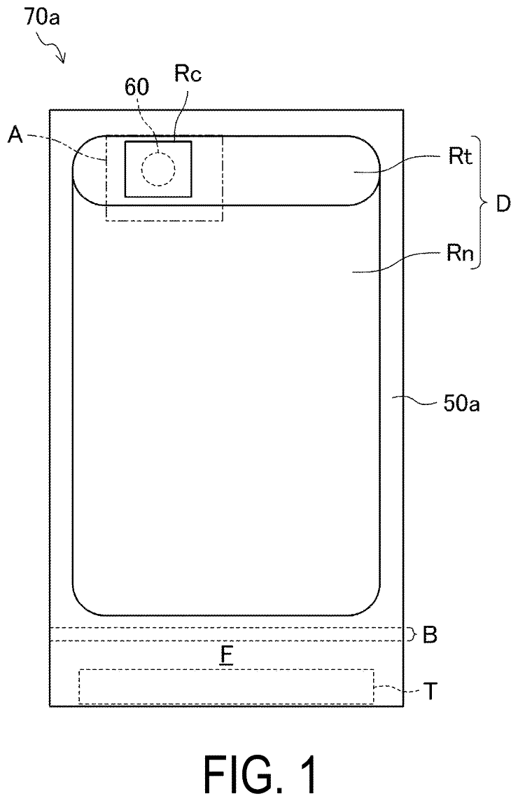

FIGS. 1 to 8 illustrate a first embodiment of a display device according to the disclosure.

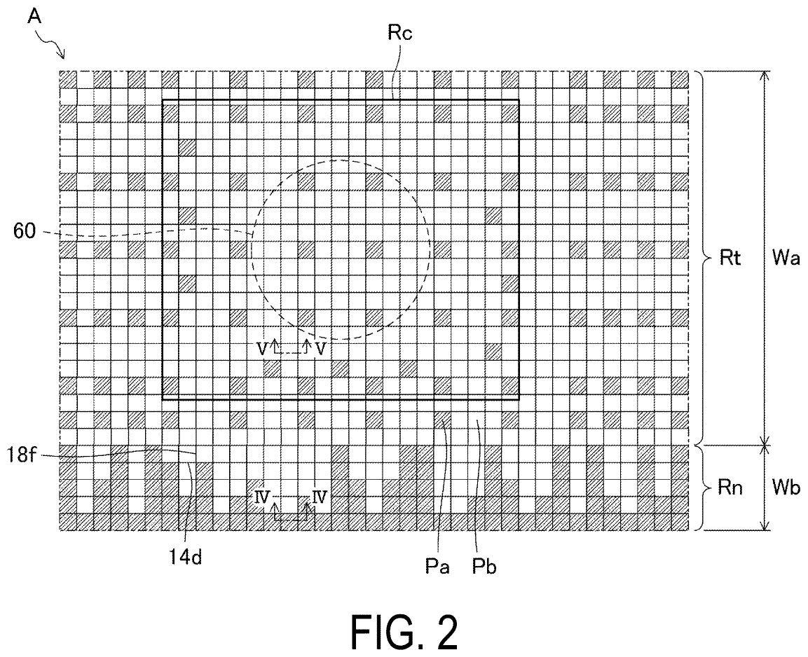

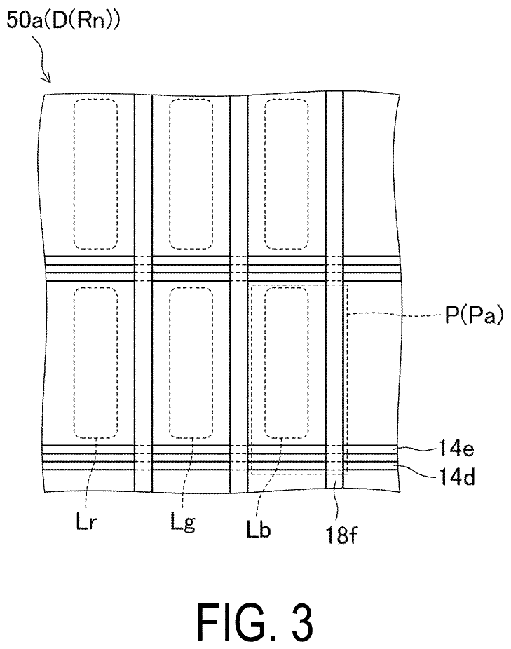

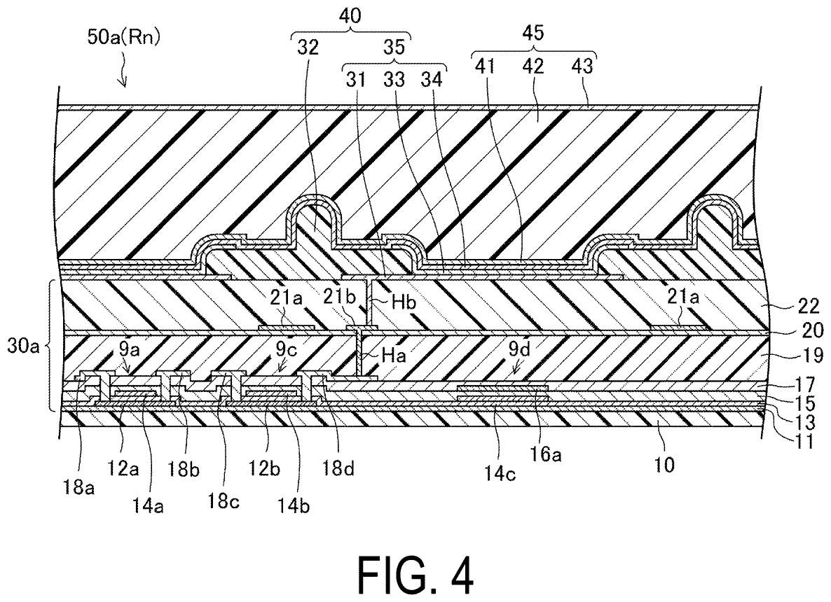

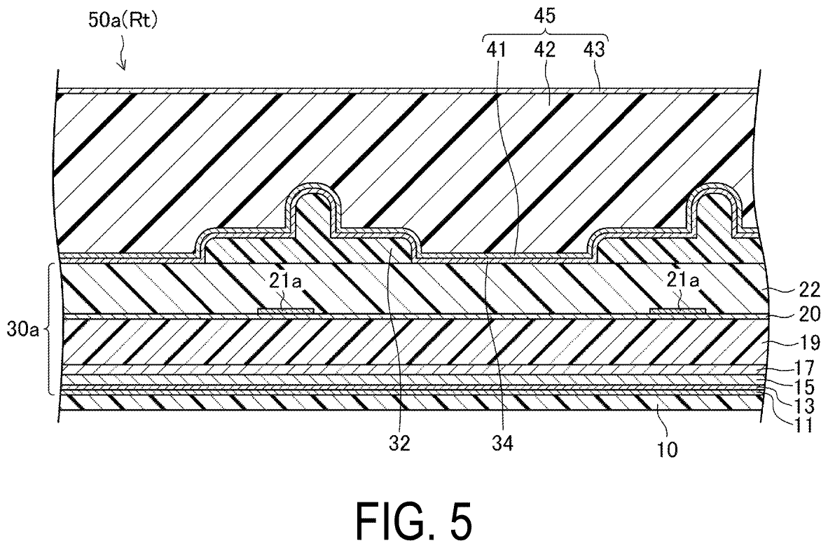

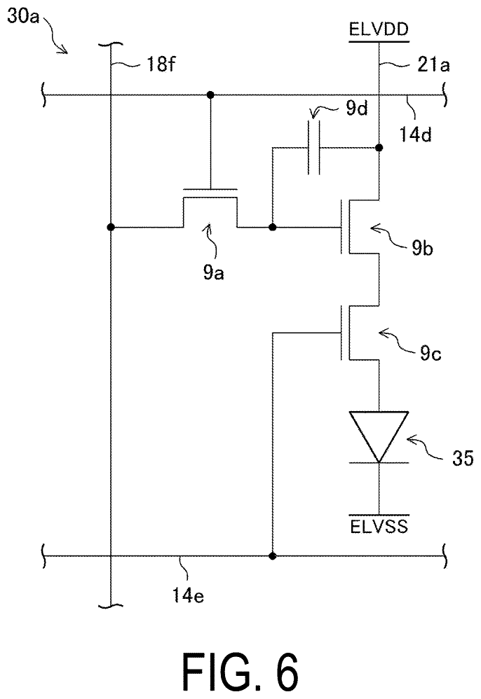

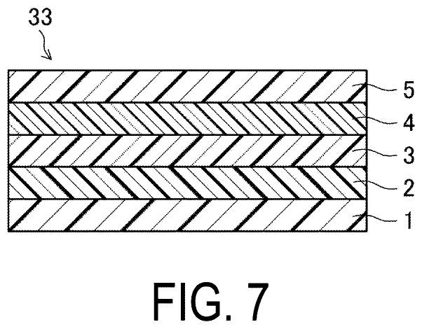

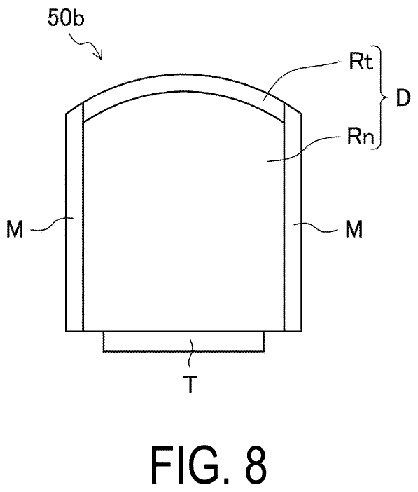

Note that, in each of the following embodiments, an organic EL display device including an organic EL element layer is exemplified as a display device including a light-emitting element layer. Here, FIG. 1 is a plan view illustrating a schematic configuration of an organic EL display device 70a according to the present embodiment. FIG. 2 is an enlarged plan view of main portions of a region A in FIG. 1. FIG. 3 is a plan view of a normal pixel region Rn in a display region D of an organic EL display panel 50a constituting the organic EL display device 70a. FIG. 4 is a cross-sectional view of the normal pixel region Rn in the display region D of the organic EL display panel 50a taken along a line IV-IV in FIG. 2. FIG. 5 is a cross-sectional view of a thinned-out pixel region Rt in the display region D of the organic EL display panel 50a taken along a line V-V in FIG. 2. FIG. 6 is an equivalent circuit diagram of a thin film transistor layer 30a constituting the organic EL display panel 50a. FIG. 7 is a cross-sectional view of an organic EL layer 33 constituting the organic EL display panel 50a. FIG. 8 is a plan view of an organic EL display panel 50b, which is a modified example of the organic EL display panel 50a.

As illustrated in FIG. 1, the organic EL display device 70a includes the organic EL display panel 50a and an imaging element 60 provided as an electronic component overlapping an image capturing region Rc described below on one front face side (the side of a resin substrate 10 described below) of the organic EL display panel 50a.

As illustrated in FIG. 1, the organic EL display panel 50a includes, for example, the display region D that is provided in a rectangular shape and in which an image is displayed, and a frame region F provided in a rectangular frame-like shape around the display region D. Note that in the present embodiment, as illustrated in FIG. 1, the rectangular display region D has rounded corners. However, this rectangular shape may include, in addition to a substantially rectangular shape with rounded corners, for example, a rectangular shape with right angle corners, a substantially rectangular shape with curved side, a substantially rectangular shape with a notch in the side, and the like.

As illustrated in FIG. 3, a plurality of subpixels P are arrayed in a matrix shape in the display region D. In addition, in the display region D, for example, the subpixel P including a red light-emitting region Lr for displaying a red color, the subpixel P including a green light-emitting region Lg for displaying a green color, and the subpixel P including a blue light-emitting region Lb for displaying a blue color are provided adjacent to one another, as illustrated in FIG. 3. Note that one pixel is configured by, for example, three adjacent subpixels P including the red light-emitting region Lr, the green light-emitting region Lg, and the blue light-emitting region Lb in the display region D. Here, since the image capturing region Rc is provided in the display region D, the subpixels P are thinned out in order to increase optical transparency in the image capturing region Rc. Thus, as illustrated in FIG. 1, the display region D includes the normal pixel region Rn provided as a first display region where the subpixels P are not thinned out, a thinned-out pixel region Rt where the subpixels P are thinned out that is provided as a second pixel region along the edge on one side of the organic EL display panel 50a and is adjacent to the normal pixel region Rn, and the image capturing region Rc provided as a third display region in the thinned-out pixel region Rt.

As illustrated in FIG. 2, in the normal pixel region Rn, a plurality of subpixels Pa that can be turned on are arranged adjacent to one another in a matrix. In addition, in the thinned-out pixel region Rt, as illustrated in FIG. 2, subpixels Pb that cannot be turned on (portions without hatching in the diagram) are arranged around the subpixels Pa that can be turned on (portions with hatching in the diagram). Here, the density (for example, about 100/mm²) of the subpixels Pa that can be turned on in the thinned-out pixel region Rt excluding the image capturing region Rc is less than the density (for example, about 500/mm²) of the subpixels Pa that can be turned on in the normal pixel region Rn and is greater than the density (for example, about 50/mm²) of the subpixels Pa that can be turned on in the image capturing region Rc. As illustrated in FIG. 2, the boundary between the subpixels Pa that can be turned on in the normal pixel region Rn and the subpixels Pb that cannot be turned on in the thinned-out pixel region Rt has a random uneven shape in a plan view. Note that a width Wb (the length in the vertical direction in FIG. 2) of the uneven portion between the normal pixel region Rn and the thinned-out pixel region Rt is about 10% of a width Wa (the length in the vertical direction in FIG. 2 (for example, about 5 mm)) of the thinned-out pixel region Rt. This is about 0.5 mm, which is equivalent to five subpixels P arranged vertically in FIG. 2.

A terminal portion T is provided at a lower end portion of the frame region F in FIG. 1 extending in one direction (lateral direction in the diagram). Further, as illustrated in FIG. 1, in the frame region F, a bending portion B that can be bent, for example, by 180° (in a U-shape) with the lateral direction in the diagram as a bending axis is provided between the display region D and the terminal portion T, and extends in one direction (the lateral direction in the diagram).

As illustrated in FIG. 4, the organic EL display panel 50a includes the resin substrate 10 provided as a base substrate, the thin film transistor (hereinafter, also referred to as a TFT) layer 30a provided on the resin substrate 10, an organic EL element layer 40 provided on the TFT layer 30a as a light-emitting element layer, and a sealing film 45 provided on the organic EL element layer 40. In the present embodiment, the organic EL display panel 50a has a rectangular shape in a plan view. However, the organic EL display panel 50b illustrated in FIG. 8 may be used. To be specific, in the organic EL display panel 50b, as illustrated in FIG. 8, the edge on the upper side in the diagram is provided in a curved arc shape in a plan view, and the thinned-out pixel region Rt constituting the display region D is provided along the curved edge. In addition, in the organic EL display panel 50b, in the frame region F (not illustrated), as illustrated in FIG. 8, a peripheral circuit portion M is provided on the outer side of both the left and right sides of the display region D in the diagram, and the terminal portion T is provided on the outer side of the lower side of the display region D in the diagram. Here, in the peripheral circuit portion M, for example, a peripheral circuit such as a gate drive circuit is monolithically formed, and in the terminal portion T, for example, a flexible printed circuit (FPC) on which an integrated circuit (IC) or the like constituting a source drive circuit is installed is mounted.

The resin substrate 10 is made, for example, of an organic resin material such as a polyimide resin or the like.

As illustrated in FIG. 4, the TFT layer 30a includes a base coat film 11 provided on the resin substrate 10; a first TFT 9a, a second TFT 9b (see FIG. 6), a third TFT 9c, and a capacitor 9d provided on the base coat film 11 for each subpixel Pa that can be turned on; and a first flattening film 19, a protective insulating film 20, and a second flattening film 22 layered sequentially in this order on the first TFT 9a, the second TFT 9b, and the third TFT 9c. In the TFT layer 30a, for the subpixels Pb of the thinned-out pixel region Rt that cannot be turned on, the first TFT 9a, the second TFT 9b, the third TFT 9c, and the capacitor 9d are not provided on the base coat film 11 (see FIG. 5).

As illustrated in FIG. 3 and FIG. 6, in the TFT layer 30a, in the display region D, a plurality of gate lines 14d are provided extending in parallel to each other in the lateral direction in the diagrams. Further, as illustrated in FIG. 3 and FIG. 6, in the TFT layer 30a, in the display region D, a plurality of light emission control lines 14e are provided extending in parallel to each other in the lateral direction in the diagrams. Note that the gate lines 14d and the light emission control lines 14e are formed of the same material in the same layer as gate electrodes 14a and 14b and a lower conductive layer 14c. Further, as illustrated in FIG. 3, each of the light emission control lines 14e is provided adjacent to each of the gate lines 14d. Further, as illustrated in FIG. 3 and FIG. 6, in the TFT layer 30a, in the display regionD, a plurality of source lines 18f are provided extending in parallel to each other in the vertical direction in the diagrams. Note that the source lines 18f are formed of the same material in the same layer as source electrodes 18a and 18c and drain electrodes 18b and 18d described below. Further, in the TFT layer 30a, in the display region D, power source lines 21a are provided in a lattice pattern. Note that, in the plan view of FIG. 2, the light emission control lines 14e are omitted. Also, in the cross-sectional views of FIGS. 4 and 5, the source lines 18f are omitted.

For example, each of the base coat film 11, a gate insulating film 13, a first interlayer insulating film 15, a second interlayer insulating film 17, and the protective insulating film 20 is constituted of a single-layer film or a layered film of an inorganic insulating film of silicon nitride, silicon oxide, silicon oxynitride, or the like.

As illustrated in FIG. 6, the first TFT 9a is electrically connected to the corresponding gate line 14d, the corresponding source line 18f, and the corresponding second TFT 9b in each subpixel Pa that can be turned on. Further, as illustrated in FIG. 4, the first TFT 9a includes a semiconductor layer 12a, the gate insulating film 13, the gate electrode 14a, the first interlayer insulating film 15, the second interlayer insulating film 17, and the source electrode 18a and the drain electrode 18b, which are provided sequentially in this order on the base coat film 11. Here, as illustrated in FIG. 4, the semiconductor layer 12a is provided on the base coat film 11, and includes a channel region, a source region, and a drain region. Further, the semiconductor layer 12a and a semiconductor layer 12b described later are formed of, for example, a polysilicon such as a low temperature polysilicon (LTPS), an In-Ga-Zn-O-based oxide semiconductor, or the like. Further, as illustrated in FIG. 4, the gate insulating film 13 is provided covering the semiconductor layer 12a. Further, as illustrated in FIG. 4, the gate electrode 14a is provided on the gate insulating film 13, overlapping with the channel region of the semiconductor layer 12a. Further, as illustrated in FIG. 4, the first interlayer insulating film 15 and the second interlayer insulating film 17 are provided sequentially in this order covering the gate electrode 14a. Further, as illustrated in FIG. 4, the source electrode 18a and the drain electrode 18b are provided separated from each other on the second interlayer insulating film 17. Further, as illustrated in FIG. 4, the source electrode 18a and the drain electrode 18b are electrically connected to the source region and the drain region of the semiconductor layer 12a, respectively, via respective contact holes formed in a layered film configured by the gate insulating film 13, the first interlayer insulating film 15, and the second interlayer insulating film 17.

As illustrated in FIG. 6, the second TFT 9b is electrically connected to the corresponding first TFT 9a, the corresponding power source line 21a, and the corresponding third TFT 9c in each subpixel Pa that can be turned on. Note that the second TFT 9b has substantially the same structure as the first TFT 9a and the third TFT 9c to be described later.

As illustrated in FIG. 6, the third TFT 9c is electrically connected to the corresponding second TFT 9a, the corresponding power source line 21a, and the corresponding light emission control line 14e in each subpixel Pa that can be turned on. Additionally, as illustrated in FIG. 4, the third TFT 9c includes the semiconductor layer 12b, the gate insulating film 13, the gate electrode 14b, the first interlayer insulating film 15, the second interlayer insulating film 17, and the source electrode 18c and the drain electrode 18d, which are provided sequentially in this order on the base coat film 11. Here, as illustrated in FIG. 4, the semiconductor layer 12b is provided on the base coat film 11, and includes a channel region, a source region, and a drain region, similarly to the semiconductor layer 12a. Further, as illustrated in FIG. 4, the gate insulating film 13 is provided covering the semiconductor layer 12b. Further, as illustrated in FIG. 4, the gate electrode 14b is provided on the gate insulating film 13, overlapping with the channel region of the semiconductor layer 12b. Further, as illustrated in FIG. 4, the first interlayer insulating film 15 and the second interlayer insulating film 17 are provided sequentially in this order covering the gate electrode 14b. Further, as illustrated in FIG. 4, the source electrode 18c and the drain electrode 18d are provided separated from each other on the second interlayer insulating film 17. Further, as illustrated in FIG. 4, the source electrode 18c and the drain electrode 18d are electrically connected to the source region and the drain region of the semiconductor layer 12b, respectively, via respective contact holes formed in the layered film configured by the gate insulating film 13, the first interlayer insulating film 15, and the second interlayer insulating film 17. Further, as illustrated in FIG. 4, the drain electrode 18d is electrically connected to a relay electrode 21b via a contact hole Ha formed in the first flattening film 19 and the protective insulating film 20.

Note that, in the present embodiment, the first TFT 9a, the second TFT 9b, and the third TFT 9c of a top gate type are exemplified, but the first TFT 9a, the second TFT 9b, and the third TFT 9c may be of a bottom gate type.

As illustrated in FIG. 6, the capacitor 9d is electrically connected to the corresponding first TFT 9a and the corresponding power source line 21a in each subpixel Pa that can be turned on. Here, the capacitor 9d includes the lower conductive layer 14c provided on the gate insulating film 13, the first interlayer insulating film 15 provided covering the lower conductive layer 14c, and an upper conductive layer 16a that is provided on the first interlayer insulating film 15 and overlaps with the lower conductive layer 14c as illustrated in FIG. 4. Note that the upper conductive layer 16a is electrically connected to the power source line 21a via a contact hole (not illustrated) formed in the second interlayer insulating film 17, the first flattening film 19, and the protective insulating film 20.

Each of the first flattening film 19, the second flattening film 22, and an edge cover 32 described later is formed of, for example, an organic resin material such as a polyimide resin, an acrylic resin, and a novolac resin.

As illustrated in FIG. 4, the relay electrode 21b is provided on the protective insulating film 20 and is formed of the same material in the same layer as the power source lines 21a.

As illustrated in FIG. 4, the organic EL element layer 40 includes a plurality of first electrodes 31, the edge cover 32, the plurality of organic EL layers 33, and a second electrode 34, which are layered sequentially in this order on the TFT layer 30a. Here, in each subpixel Pa that can be turned on, as illustrated in FIG. 4, an organic EL element 35 is constituted of the first electrode 31, the organic EL layer 33, and the second electrode 34 layered sequentially in this order on the second flattening film 22.

As illustrated in FIG. 4, the plurality of first electrodes 31 are provided in a matrix shape on the second flattening film 22, corresponding to the plurality of subpixels Pa that can be turned on. Here, as illustrated in FIG. 4, the first electrode 31 is electrically connected to the drain electrode 18d of each of the third TFTs 9c via the contact hole Ha formed in the first flattening film 19 and the protective insulating film 20, the relay electrode 21b, and a contact hole Hb formed in the second flattening film 22. The first electrode 31 and the organic EL layer 33 are not provided on the second flattening film 22 in the subpixel Pb of the thinned-out pixel region Rt that cannot be turned on (see FIG. 5). Further, the first electrode 31 functions to inject holes (positive holes) into the organic EL layer 33. Further, the first electrode 31 is preferably made of a material having a high work function to improve the efficiency of hole injection into the organic EL layer 33. Here, examples of materials constituting the first electrode 31 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Examples of the materials constituting the first electrode 31 may include alloy such as astatine (At)/astatine oxide (AtO2). Furthermore, examples of the materials constituting the first electrode 31 may include electrically conductive oxide such as tin oxide (SnO), zinc oxide (ZnO), indium tin oxide (ITO), and indium zinc oxide (IZO). Additionally, the first electrode 31 may be formed by layering a plurality of layers made of any of the materials described above.

Note that examples of compound materials having a high work function include indium tin oxide (ITO) and indium zinc oxide (IZO).

As illustrated in FIG. 4, the edge cover 32 is common to the plurality of subpixels P (including the subpixels Pa that can be turned on and the subpixels Pb that cannot be turned on), and is provided in a lattice pattern covering a peripheral end portion of each of the first electrodes 31.

As illustrated in FIG. 4, the plurality of organic EL layers 33 are disposed on the plurality of first electrodes 31, and are provided, as light-emitting function layers, in a matrix shape, corresponding to the plurality of subpixels Pa that can be turned on. Here, as illustrated in FIG. 7, each of the organic EL layers 33 includes a hole injection layer 1, a hole transport layer 2, a light-emitting layer 3, an electron transport layer 4, and an electron injection layer 5, which are provided sequentially in this order on the first electrode 31.

The hole injection layer 1 is also referred to as an anode electrode buffer layer, and functions to reduce an energy level difference between the first electrode 31 and the organic EL layer 33 to thereby improve the efficiency of hole injection into the organic EL layer 33 from the first electrode 31. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 functions to improve the efficiency of hole transport from the first electrode 31 to the organic EL layer 33. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where holes and electrons are injected from the first electrode 31 and the second electrode 34, respectively, and the holes and the electrons recombine, in a case where a voltage is applied via the first electrode 31 and the second electrode 34. Here, the light-emitting layer 3 is formed of a material having high luminous efficiency. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of causing electrons to efficiently migrate to the light-emitting layer 3. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 functions to reduce an energy level difference between the second electrode 34 and the organic EL layer 33 to thereby improve the efficiency of electron injection into the organic EL layer 33 from the second electrode 34, and this function allows the drive voltage of the organic EL element 35 to be reduced. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 4, the second electrode 34 is common to the plurality of subpixels P (including the subpixels Pa that can be turned on and the subpixels Pb that cannot be turned on), and is provided covering each of the organic EL layers 33 and the edge cover 32. Further, the second electrode 34 functions to inject electrons into the organic EL layer 33. Further, the second electrode 34 is preferably formed of a material having a low work function to improve the efficiency of electron injection into the organic EL layer 33. Here, examples of a material constituting the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Further, the second electrode 34 may be formed of alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), and lithium fluoride (LiF)/calcium (Ca)/aluminum (Al). Further, the second electrode 34 may be formed of an electrically conductive oxide such as tin oxide (SnO), zinc oxide (ZnO), indium tin oxide (ITO), and indium zinc oxide (IZO). Further, the second electrode 34 may be formed by layering a plurality of layers formed of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As illustrated in FIG. 4 and FIG. 5, the sealing film 45 is provided covering the second electrode 34, includes a first inorganic sealing film 41, an organic sealing film 42, and a second inorganic sealing film 43 layered sequentially in this order on the second electrode 34, and functions to protect each organic EL layer 33 of the organic EL element 35 from moisture, oxygen, and the like. Here, the first inorganic sealing film 41 and the second inorganic sealing film 43 include, for example, an inorganic insulating film such as a silicon nitride film, a silicon oxide film, and a silicon oxynitride film. Additionally, the organic sealing film 42 is made of, for example, an organic resin material such as an acrylic resin, an epoxy resin, a silicone resin, a polyurea resin, a parylene resin, a polyimide resin, and a polyamide resin.

Further, the imaging element 60 is constituted of, for example, a complementary metal oxide semiconductor (CMOS) camera, a charge coupled device (CCD) camera, or the like. Note that in the present embodiment, the imaging element 60 is exemplified as an electronic component, and the electronic component may be a fingerprint sensor, a facial authentication sensor, or similar optical sensor, for example.

In the organic EL display device 70a described above, in each of the subpixels Pa that can be turned on, by inputting a gate signal to the first TFT 9a via the gate line 14d, the first TFT 9a is turned on. When a predetermined voltage corresponding to a source signal is written to the gate electrode 14b of the second TFT 9b and the capacitor 9d via the source line 18f, and a light emission control signal is input to the third TFT 9c via the light emission control line 14e, the third TFT 9c is turned on. Then, by supplying a current corresponding to the gate voltage of the second TFT 9b from the power source line 21a to the organic EL element 35, the light-emitting layer 3 of the organic EL element 35 emits light to display an image. Note that, in the organic EL display device 70a, even when the first TFT 9a is turned off, the gate voltage of the second TFT 9b is held by the capacitor 9d, and thus, light emission by the light-emitting layer 3 is maintained in each of the subpixels Pa that can be turned on until a gate signal of the next frame is input. Further, the organic EL display device 70a is configured to capture an image on the front face side of the organic EL display panel 50a through the organic EL display panel 50a, using the imaging element 60 installed on the back face side of the organic EL display panel 50a.

Next, a method for manufacturing the organic EL display device 70a according to the present embodiment will be described. Here, the method for manufacturing the organic EL display device 70a according to the present embodiment includes a TFT layer forming step, an organic EL element layer forming step, and a sealing film forming step.

### TFT Layer Forming Step

First, for example, a non-photosensitive polyimide resin (having a thickness of approximately 6 μm) is applied onto a glass substrate, and then the applied film is prebaked and postbaked to form the resin substrate 10.

Subsequently, a silicon oxide film (having a thickness of approximately 500 nm) and a silicon nitride film (having a thickness of approximately 100 nm) are sequentially formed, for example, by a plasma chemical vapor deposition (CVD) method, on the substrate surface on which the resin substrate 10 is formed, to form the base coat film 11.

Thereafter, for example, an amorphous silicon film (having a thickness of approximately 30 nm to 100 nm) is formed, by the plasma CVD method, on the substrate surface on which the base coat film 11 is formed, the amorphous silicon film is crystallized by laser annealing or the like to form a semiconductor film of a polysilicon film, and then, the semiconductor film is patterned to form the semiconductor layers 12a and 12b, and the like.

Furthermore, an inorganic insulating film (of approximately 100 nm) such as a silicon oxide film is formed, for example, by a plasma CVD method, on the substrate surface on which the semiconductor layer 12a and the like are formed, to form the gate insulating film 13 to cover the semiconductor layer 12a and the like.

Subsequently, a molybdenum film (having a thickness of approximately 100 nm to 400 nm) is formed, for example, by a sputtering method, on the substrate surface on which the gate insulating film 13 is formed, and then, the molybdenum film is patterned to form the gate electrodes 14a and 14b and the like.

Thereafter, by doping impurity ions using the gate electrodes 14a and 14b as a mask, a portion of each of the semiconductor layers 12a and 12b is made conductive.

Furthermore, a silicon nitride film (having a thickness of approximately 50 nm to 200 nm) is formed, for example, by a plasma CVD method, on the substrate surface on which a portion of the semiconductor layer 12a and the like has been made conductive, to form the first interlayer insulating film 15.

Subsequently, a molybdenum film (having a thickness of approximately 100 nm to 400 nm) is formed, for example, by a sputtering method, on the substrate surface on which the first interlayer insulating film 15 is formed, and then, the molybdenum film is patterned to form the upper conductive layer 16a and the like.

Thereafter, a silicon oxide film (having a thickness of approximately 100 nm to 500 nm) and a silicon nitride film (having a thickness of approximately 100 nm to 300 nm) are sequentially formed, for example, by a plasma CVD method, on the substrate surface on which the upper conductive layer 16a and the like are formed, to form the second interlayer insulating film 17.

Furthermore, the gate insulating film 13, the first interlayer insulating film 15, and the second interlayer insulating film 17 are patterned to form a contact hole.

Subsequently, a titanium film (having a thickness of approximately 50 nm), an aluminum film (having a thickness of approximately 600 nm), and a titanium film (having a thickness of approximately 50 nm) are sequentially formed, for example, by a sputtering method, on the substrate surface in which the above-described contact hole is formed, and then, a metal layered film thereof is patterned to form the source electrodes 18a and 18c, the drain electrodes 18b and 18d, and the like.

Thereafter, a photosensitive polyimide resin (having a thickness of approximately 2.5 μm) is applied, for example, by a spin coating method or a slit coating method onto the substrate surface on which the source electrode 18a and the like are formed, and then, the applied film is prebaked, exposed, developed, and postbaked to form the first flattening film 19.

Furthermore, a silicon nitride film (having a thickness of approximately 100 nm to 500 nm) is sequentially formed, for example, by a plasma CVD method, on the substrate surface on which the first flattening film 19 is formed, and then, the silicon nitride film is patterned to form the protective insulating film 20 provided with an upper portion of the contact hole Ha.

Thereafter, the first flattening film 19 exposed from the contact hole Ha of the protective insulating film 20 is etched to form a lower portion of the contact hole Ha in the first flattening film 19.

Then, a titanium film (having a thickness of approximately 50 nm), an aluminum film (having a thickness of approximately 600 nm), and a titanium film (having a thickness of approximately 50 nm) are sequentially formed, for example, by a sputtering method, on the substrate surface on which the entire contact hole Ha is formed, and then, a metal layered film thereof is patterned to form the power source line 21a, the relay electrode 21b, and the like.

Finally, a photosensitive polyimide resin (having a thickness of approximately 2.5 μm) is applied, for example, by a spin coating method or a slit coating method onto the substrate surface on which the power source lines 21a and the like are formed, and then, the applied film is prebaked, exposed, developed, and postbaked to form the second flattening film 22 provided with the contact hole Hb.

As described above, the Tft layer 30a can be formed.

### Organic EL Element Layer Forming Step

The organic EL element layer 40 is formed by forming the first electrode 31, the edge cover 32, the organic EL layer 33 (the hole injection layer 1, the hole transport layer 2, the light-emitting layer 3, the electron transport layer 4, the electron injection layer 5), and the second electrode 34 on the second flattening film 22 of the TFT layer 30a having been formed in the TFT layer forming step, by using a known method.

### Sealing Film Forming Step

First, an inorganic insulating film such as a silicon nitride film, a silicon oxide film, or a silicon oxynitride film is formed by plasma CVD on a substrate surface formed with the organic EL element layer 40 formed in the organic EL element layer forming step described above by using a mask to form the first inorganic sealing film 41.

Next, on the substrate surface formed of the first inorganic sealing film 41, a film made of an organic resin material such as acrylic resin is formed by, for example, using an ink-jet method to form the organic sealing film 42.

Next, an inorganic insulating film such as a silicon nitride film, a silicon oxide film, or a silicon oxynitride film is formed by plasma CVD on the substrate formed with the organic sealing film 42 by using a mask to form the second inorganic sealing film 43, thereby forming the sealing film 45.

The organic EL display panel 50a of the present embodiment can be manufactured as described above.

Furthermore, when the organic EL display panel 50a manufactured in this manner is fixed, for example, to the interior of a housing, the organic EL display device 70a can be manufactured by installing the imaging element 60 on the back face side of the image capturing region Rc of the organic EL display panel 50a.

As described above, according to the organic EL display device 70a of the present embodiment, the thinned-out pixel region Rt including the image capturing region Rc is provided along one side of the organic EL display panel 50a, and the density of the subpixels Pa that can be turned on in the thinned-out pixel region Rt other than the image capturing region Rc is less than the density of the subpixels Pa that can be turned on in the normal pixel region Rn and is greater than the density of the subpixels Pa that can be turned on in the image capturing region Rc. Thus, the thinned-out pixel region Rt other than the image capturing region Rc where the subpixels Pa that can be turned on are arranged at a relatively medium density is arranged between the image capturing region Rc where the subpixels Pa that can be turned on are arranged at a relatively low density and the normal pixel region Rn where the subpixels Pa that can be turned on are arranged at a relatively high density. Accordingly, the thinned-out pixel region Rt other than the image capturing region Rc becomes a buffer region that alleviates a change in the density of the subpixels Pa that can be turned on, and thus it is possible to make the boundary between the image capturing region Rc where the subpixels are thinned out and the normal pixel region Rn where the subpixels are not thinned out less visually recognizable.

In addition, according to the organic EL display device 70a of the present embodiment, since the boundary between the subpixel Pa that can be turned on in the normal pixel region Rn and the subpixel Pb that cannot be turned on in the thinned-out pixel region Rt has an uneven shape in a plan view, the boundary can be made unclear. Accordingly, since the boundary between the normal pixel region Rn and the thinned-out pixel region Rt can be made difficult to be visually recognized, the boundary between the image capturing region Rc where the subpixels are thinned out and the normal pixel region Rn where the subpixels are not thinned out can be made even more difficult to be visually recognized.

### Second Embodiment

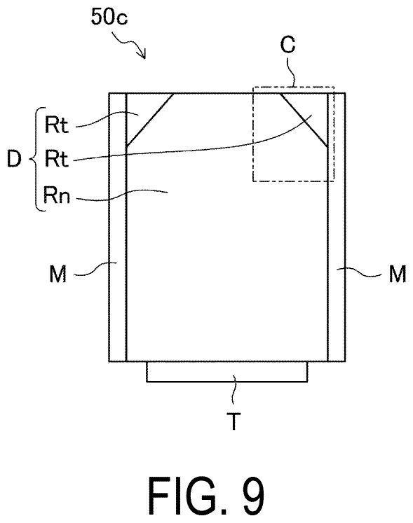

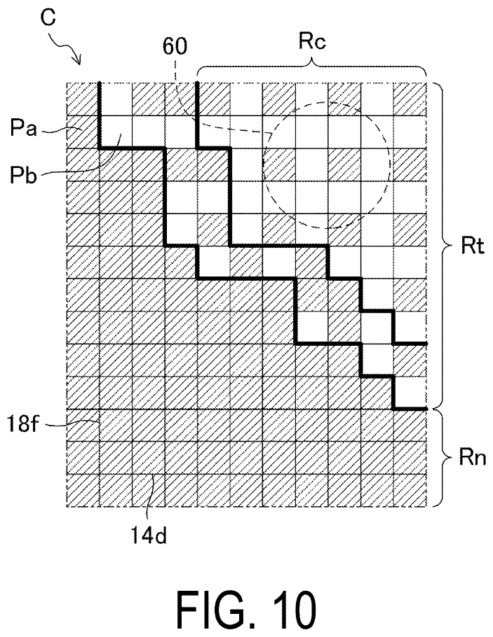

FIGS. 9 and 10 illustrate a second embodiment of a display device according to the disclosure. Here, FIG. 9 is a plan view of an organic EL display panel 50c constituting an organic EL display device of the present embodiment. FIG. 10 is an enlarged plan view of main portions of a region C in FIG. 9. Note that, in each of the following embodiments, the same portions as those in FIG. 1 to FIG. 8 are denoted by the same reference signs, and detailed description of these portions is omitted.

In the first embodiment, the organic EL display device 70a with the thinned-out pixel region Rt provided along one side of the organic EL display panel 50a has been described. However, in the present embodiment, an organic EL display device with the thinned-out pixel region Rt provided along the corner of the organic EL display panel 50c is described. The organic EL display device of the present embodiment has substantially the same configuration as that of the organic EL display device 70a except that the organic EL display panel 50c is used instead of the organic EL display panel 50b of the modified example of the organic EL display panel 50a in the first embodiment, and thus the organic EL display panel 50c will be mainly described.

The organic EL display panel 50c, as with the organic EL display panel 50a of the first embodiment described above, includes the display region D and the frame region F provided around the display region D. Here, in the organic EL display panel 50c, as illustrated in FIG. 9, the thinned-out pixel region Rt constituting the display region D is provided along each corner of both end portions of one side on the upper side in the diagram. As illustrated in FIG. 10, the image capturing region Rc is provided in each thinned-out pixel region Rt. In the organic EL display panel 50c, the density of the subpixels Pa that can be turned on in the thinned-out pixel region Rt other than the image capturing region Rc is less than the density of the subpixels Pa that can be turned on in the normal pixel region Rn and greater than the density of the subpixels Pa that can be turned on in the image capturing region Rc, as in the organic EL display panel 50a of the first embodiment. As illustrated in FIG. 10, the boundary between the subpixels Pa that can be turned on in the normal pixel region Rn and the subpixels Pb that cannot be turned on in the thinned-out pixel region Rt has a random uneven shape in a plan view.

As with the organic EL display panel 50a of the first embodiment described above, the organic EL display panel 50c includes the resin substrate 10, the TFT layer 30a provided on the resin substrate 10, the organic EL element layer 40 provided on the TFT layer 30a, and the sealing film 45 provided on the organic EL element layer 40.

Similarly to the organic EL display device 70a of the first embodiment described above, the organic EL display device including the organic EL display panel 50c is configured to display an image by causing the light-emitting layer 3 of the organic EL element 35 to emit light as appropriate via the first TFT 9a, the second TFT 9b, and the third TFT 9c in each of the subpixels Pa that can be turned on. Further, the organic EL display device including the organic EL display panel 50c is configured to capture an image on the front face side of the organic EL display panel 50c through the organic EL display panel 50c, using the imaging element 60 installed on the back face side of the organic EL display panel 50c.

The organic EL display device including the organic EL display panel 50c of the present embodiment can be manufactured by changing the arrangement of the subpixels Pa that can be turned on and the subpixels Pb that cannot be turned on in the method for manufacturing the organic EL display device 70a of the first embodiment described above.

As described above, according to the organic EL display device including the organic EL display panel 50c of the present embodiment, the thinned-out pixel region Rt including the image capturing region Rc is provided along the corners of the organic EL display panel 50c, and the density of the subpixels Pa that can be turned on in the thinned-out pixel region Rt other than the image capturing region Rc is less than the density of the subpixels Pa that can be turned on in the normal pixel region Rn and is greater than the density of the subpixels Pa that can be turned on in the image capturing region Rc. Thus, the thinned-out pixel region Rt other than the image capturing region Rc where the subpixels Pa that can be turned on are arranged at a relatively medium density is arranged between the image capturing region Rc where the subpixels Pa that can be turned on are arranged at a relatively low density and the normal pixel region Rn where the subpixels Pa that can be turned on are arranged at a relatively high density. Accordingly, the thinned-out pixel region Rt other than the image capturing region Rc becomes a buffer region that alleviates a change in the density of the subpixels Pa that can be turned on, and thus it is possible to make the boundary between the image capturing region Rc where the subpixels are thinned out and the normal pixel region Rn where the subpixels are not thinned out less visually recognizable.

In addition, according to the organic EL display device including the organic EL display panel 50c of the present embodiment, since the boundary between the subpixel Pa that can be turned on in the normal pixel region Rn and the subpixel Pb that cannot be turned on in the thinned-out pixel region Rt has an uneven shape in a plan view, the boundary can be made unclear. Accordingly, since the boundary between the normal pixel region Rn and the thinned-out pixel region Rt can be made difficult to be visually recognized, the boundary between the image capturing region Rc where the subpixels are thinned out and the normal pixel region Rn where the subpixels are not thinned out can be made even more difficult to be visually recognized.

### Third Embodiment

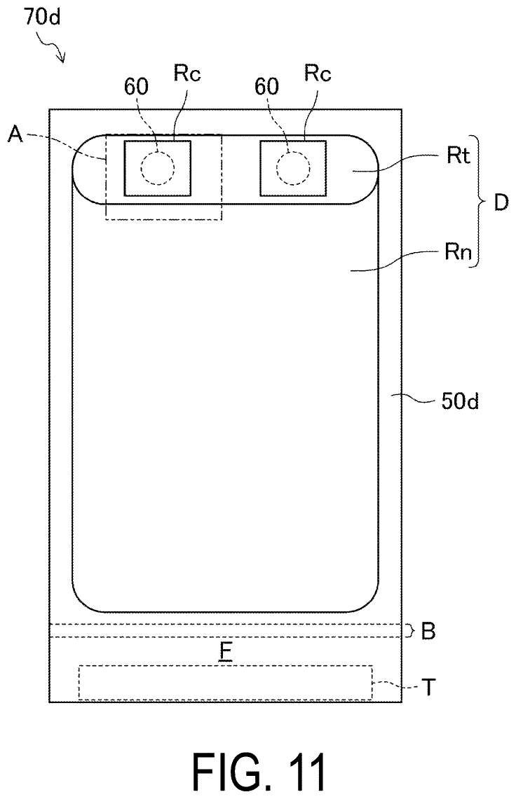

FIG. 11 illustrates a third embodiment of the display device according to the disclosure. FIG. 11 is a plan view of an organic EL display device 70d of the present embodiment.

In the first embodiment, the organic EL display device 70a with one image capturing region Rc provided in the thinned-out pixel region Rt of the organic EL display panel 50a has been described. However, in the present embodiment, the organic EL display device 70d with two image capturing region Rc provided in the thinned-out pixel region Rt of the organic EL display panel 50d is described.

As illustrated in FIG. 11, the organic EL display device 70d includes the organic EL display panel 50d and two imaging elements 60 that are provided on one front face side of the organic EL display panel 50d and respectively overlap with each image capturing region Rc of the thinned-out pixel region Rt.

The organic EL display panel 50d, as with the organic EL display panel 50a of the first embodiment described above, includes the display region D and the frame region F provided around the display region D. Here, in the organic EL display panel 50d, as illustrated in FIG. 11, the display region D includes the normal pixel region Rn, the thinned-out pixel region Rt that is provided along the edge of one side (upper side in the diagram) of the organic EL display panel 50d and is adjacent to the normal pixel region Rn, and two image capturing regions Rc provided inside the thinned-out pixel region Rt. In the organic EL display panel 50d, the density of the subpixels Pa that can be turned on in the thinned-out pixel region Rt other than the image capturing region Rc is less than the density of the subpixels Pa that can be turned on in the normal pixel region Rn and greater than the density of the subpixels Pa that can be turned on in the image capturing region Rc, as in the organic EL display panel 50a of the first embodiment.

As with the organic EL display panel 50a and 50b of the first embodiment described above, the organic EL display panel 50d includes the resin substrate 10, the TFT layer 30a provided on the resin substrate 10, the organic EL element layer 40 provided on the TFT layer 30a, and the sealing film 45 provided on the organic EL element layer 40.

In the present embodiment, the organic EL display device 70d in which two image capturing regions Rc are provided in the thinned-out pixel region Rt is described, but three or more image capturing regions Rc may be provided in the thinned-out pixel region Rt. In the present embodiment, the organic EL display device 70d with two image capturing region Rc provided in the thinned-out pixel region Rt of the organic EL display panel 50d corresponding to the organic EL display panel 50a is described. However, a plurality of the image capturing regions Rc may be provided in the thinned-out pixel region Rt of the organic EL display panel 50b of the modified example of the first embodiment and the organic EL display panel 50c of the second embodiment.

Similarly to the organic EL display device 70a of the first embodiment described above, the organic EL display device 70d of the present embodiment is configured to display an image by causing the light-emitting layer 3 of the organic EL element 35 to emit light as appropriate via the first TFT 9a, the second TFT 9b, and the third TFT 9c in each of the subpixels Pa that can be turned on. Further, the organic EL display device 70d is configured to capture an image on the front face side of the organic EL display panel 50d through the organic EL display panel 50d, using each imaging element 60 installed on the back face side of the organic EL display panel 50d.

The organic EL display device 70d of the present embodiment can be manufactured by changing the arrangement of the subpixels Pa that can be turned on and the subpixels Pb that cannot be turned on in the method for manufacturing the organic EL display device 70a of the first embodiment described above.

As described above, according to the organic EL display device 70d of the present embodiment, the thinned-out pixel region Rt including two image capturing regions Rc is provided along one side of the organic EL display panel 50d, and the density of the subpixels Pa that can be turned on in the thinned-out pixel region Rt other than the image capturing region Rc is less than the density of the subpixels Pa that can be turned on in the normal pixel region Rn and is greater than the density of the subpixels Pa that can be turned on in the image capturing region Rc. Thus, the thinned-out pixel region Rt other than the image capturing region Rc where the subpixels Pa that can be turned on are arranged at a relatively medium density is arranged between the image capturing region Rc where the subpixels Pa that can be turned on are arranged at a relatively low density and the normal pixel region Rn where the subpixels Pa that can be turned on are arranged at a relatively high density. Accordingly, the thinned-out pixel region Rt other than the image capturing region Rc becomes a buffer region that alleviates a change in the density of the subpixels Pa that can be turned on, and thus it is possible to make the boundary between the image capturing region Rc where the subpixels are thinned out and the normal pixel region Rn where the subpixels are not thinned out less visually recognizable.

In addition, according to the organic EL display device 70d of the present embodiment, since the boundary between the subpixel Pa that can be turned on in the normal pixel region Rn and the subpixel Pb that cannot be turned on in the thinned-out pixel region Rt has an uneven shape in a plan view, the boundary can be made unclear. Accordingly, since the boundary between the normal pixel region Rn and the thinned-out pixel region Rt can be made difficult to be visually recognized, the boundary between the image capturing region Rc where the subpixels are thinned out and the normal pixel region Rn where the subpixels are not thinned out can be made even more difficult to be visually recognized.

In addition, according to the organic EL display device 70d of the present embodiment, since the plurality of image capturing regions Rc are provided in the thinned-out pixel region Rt, the thinned-out pixel region Rt can be shared by the plurality of image capturing regions Rc. In addition, since the imaging element 60 is provided in each image capturing region Rc in the thinned-out pixel region Rt, it is possible to capture a detailed image using the plurality of imaging elements 60.

### Fourth Embodiment

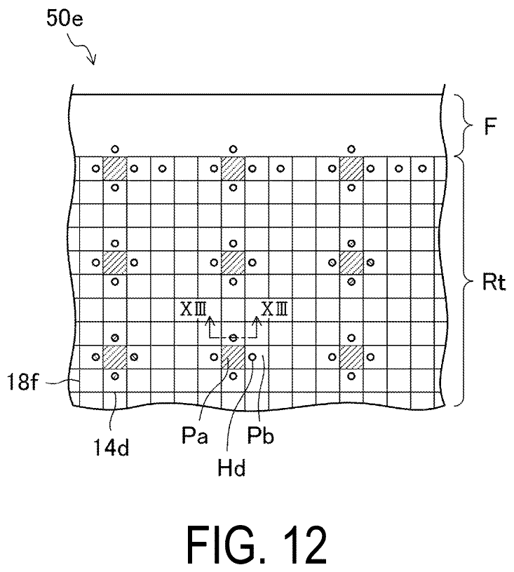

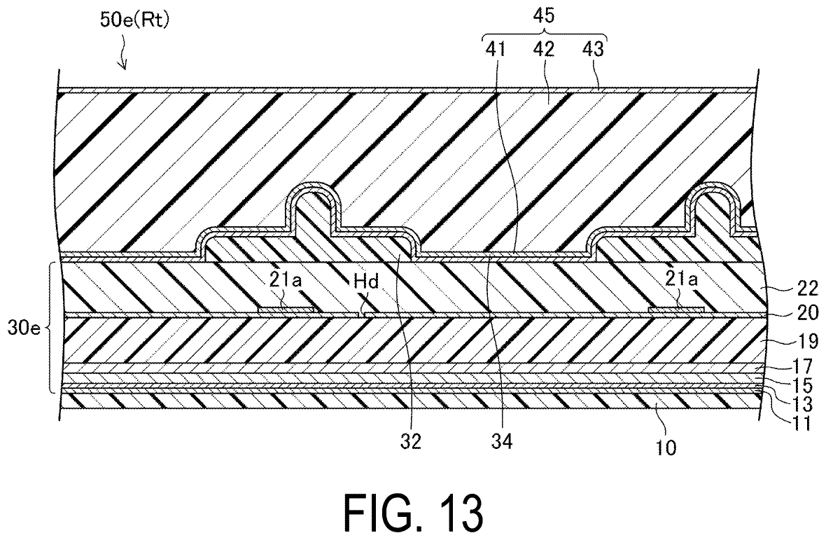

FIG. 12 and FIG. 13 illustrate a fourth embodiment of a display device according to the disclosure. Here, FIG. 12 is a plan view of an organic EL display panel 50e constituting an organic EL display device of the present embodiment. Further, FIG. 13 is a cross-sectional view of the thinned-out pixel region Rt of the organic EL display panel 50e taken along a line XIII-XIII in FIG. 12. Note that, in the cross-sectional view of FIG. 13, the source lines 18f are omitted.

In the first embodiment, the organic EL display device 70a provided with the organic EL display panel 50a where a through-hole is not formed in the protective insulating film 20 in the subpixels Pb that cannot be turned on is described. However, in the present embodiment, an organic EL display device provided with the organic EL display panel 50e where a through-hole Hd is formed in the protective insulating film 20 in the subpixels Pb that cannot be turned on is described. The organic EL display device of the present embodiment has substantially the same configuration as that of the organic EL display device 70a except that the organic EL display panel 50e is used instead of the organic EL display panel 50a in the first embodiment, and thus the organic EL display panel 50e will be mainly described.

The organic EL display panel 50e, as with the organic EL display panel 50a of the first embodiment described above, includes the display region D and the frame region F provided around the display region D. Here, in the organic EL display panel 50e, as with the organic EL display panel 50a of the first embodiment, the display region D includes the normal pixel region Rn, the thinned-out pixel region Rt that is provided along the edge of one side of the organic EL display panel 50e and is adjacent to the normal pixel region Rn, and the image capturing region Rc provided inside the thinned-out pixel region Rt. In the organic EL display panel 50e, the density of the subpixels Pa that can be turned on in the thinned-out pixel region Rt other than the image capturing region Rc is less than the density of the subpixels Pa that can be turned on in the normal pixel region Rn and greater than the density of the subpixels Pa that can be turned on in the image capturing region Rc, as in the organic EL display panel 50a of the first embodiment.

As illustrated in FIG. 13, the organic EL display panel 50e includes the resin substrate 10, the TFT layer 30e provided on the resin substrate 10, the organic EL element layer 40 provided on the TFT layer 30e, and the sealing film 45 provided on the organic EL element layer 40.

As with the TFT layer 30a of the first embodiment, the TFT layer 30e includes the base coat film 11 provided on the resin substrate 10; the first TFT 9a, the second TFT 9b, the third TFT 9c, and the capacitor 9d provided on the base coat film 11 for each subpixel Pa that can be turned on; and the first flattening film 19, the protective insulating film 20, and the second flattening film 22 layered sequentially in this order on the first TFT 9a, the second TFT 9b, and the third TFT 9c. Here, in the TFT layer 30e, as with the TFT layer 30a of the first embodiment, in the subpixels Pb that cannot be turned on of the thinned-out pixel region Rt, the first TFT 9a, the second TFT 9b, the third TFT 9c, and the capacitor 9d are not provided on the base coat film 11. However, as illustrated in FIG. 12 and FIG. 13, in some of the subpixels Pb that cannot be turned on, the through-hole Hd corresponding to the contact hole Ha is provided in the protective insulating film 20. As illustrated in FIG. 12, more through-holes Hd are formed on the edge side (upper side in the diagram) of the organic EL display panel 50e of the thinned-out pixel region Rt than on the normal pixel region Rn side (lower side in the diagram) of the thinned-out pixel region Rt, and the through-holes Hd are also formed in the frame region F (outside the display region D) on the edge side of the organic EL display panel 50e.

Similarly to the TFT layer 30a of the first embodiment described above, in the TFT layer 30e, the plurality of gate lines 14d, the plurality of light emission control lines 14e, the plurality of source lines 18f, and the power source lines 21a are provided in the display region D.

Similarly to the organic EL display device 70a of the first embodiment described above, the organic EL display device including the organic EL display panel 50e is configured to display an image by causing the light-emitting layer 3 of the organic EL element 35 to emit light as appropriate via the first TFT 9a, the second TFT 9b, and the third TFT 9c in each of the subpixels Pa that can be turned on. Further, the organic EL display device including the organic EL display panel 50e is configured to capture an image on the front face side of the organic EL display panel 50e through the organic EL display panel 50e, using the imaging element 60 installed on the back face side of the organic EL display panel 50e.

The organic EL display device including the organic EL display panel 50e of the present embodiment can be manufactured via the method for manufacturing the organic EL display device 70a of the first embodiment in addition to, after the through-holes Hd are formed when forming the contact holes Ha in the protective insulating film 20, etching the first flattening film 19 to be exposed from the contact holes Ha of the protective insulating film 20 and etching the first flattening film 19 to be exposed from the through-holes Hd of the protective insulating film 20.

As described above, according to the organic EL display device including the organic EL display panel 50e of the present embodiment, the thinned-out pixel region Rt including the image capturing region Rc is provided along one side of the organic EL display panel 50e, and the density of the subpixels Pa that can be turned on in the thinned-out pixel region Rt other than the image capturing region Rc is less than the density of the subpixels Pa that can be turned on in the normal pixel region Rn and is greater than the density of the subpixels Pa that can be turned on in the image capturing region Rc. Thus, the thinned-out pixel region Rt other than the image capturing region Rc where the subpixels Pa that can be turned on are arranged at a relatively medium density is arranged between the image capturing region Rc where the subpixels Pa that can be turned on are arranged at a relatively low density and the normal pixel region Rn where the subpixels Pa that can be turned on are arranged at a relatively high density. Accordingly, the thinned-out pixel region Rt other than the image capturing region Rc becomes a buffer region that alleviates a change in the density of the subpixels Pa that can be turned on, and thus it is possible to make the boundary between the image capturing region Rc where the subpixels are thinned out and the normal pixel region Rn where the subpixels are not thinned out less visually recognizable.

In addition, according to the organic EL display device including the organic EL display panel 50e of the present embodiment, since the boundary between the subpixel Pa that can be turned on in the normal pixel region Rn and the subpixel Pb that cannot be turned on in the thinned-out pixel region Rt has an uneven shape in a plan view, the boundary can be made unclear. Accordingly, since the boundary between the normal pixel region Rn and the thinned-out pixel region Rt can be made difficult to be visually recognized, the boundary between the image capturing region Rc where the subpixels are thinned out and the normal pixel region Rn where the subpixels are not thinned out can be made even more difficult to be visually recognized.

In addition, according to the organic EL display device including the organic EL display panel 50e of the present embodiment, since the through-holes Hd are formed in the protective insulating film 20 in a portion of the subpixels Pb that cannot be turned on in the thinned-out pixel region Rt, the gas generated from the first flattening film 19 can be gradually released from the through-holes Hd. Accordingly, peeling between the first flattening film 19 and the protective insulating film 20 can be suppressed, and the pixel circuit of the TFT layer 30e can be reliably operated, so that the occurrence of lighting failure can be suppressed. In each of the subpixels Pb that cannot be turned on in the thinned-out pixel region Rt, in a case where the through-holes Hd are not formed in the protective insulating film 20, the gas generated from the first flattening film 19 is likely to be accumulated between the first flattening film 19 and the protective insulating film 20. Thus, peeling between the first flattening film 19 and the protective insulating film 20 may be caused by the accumulated gas being discharged all at once.

Further, according to the organic EL display device including the organic EL display panel 50e of the present embodiment, more through-holes Hd formed in the protective insulating film 20 are formed on the edge side of the organic EL display panel 50e of the thinned-out pixel region Rt than on the normal pixel region Rn side of the thinned-out pixel region Rt, and the through-holes Hd are also formed in the frame region F outside the display region D on the edge side of the organic EL display panel 50e. Thus, peeling between the first flattening film 19 and the protective insulating film 20 can be effectively suppressed. Here, in the frame region F, since the contact holes Ha for electrically connecting the first electrodes 31 and the third TFTs 9c are not provided in the protective insulating film 20, the gas generated from the first flattening film 19 is likely to be accumulated between the first flattening film 19 and the protective insulating film 20.

### Other Embodiments

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

In each of the embodiments described above, the organic EL display device including the first electrode as an anode electrode and the second electrode as a cathode electrode is exemplified. The disclosure is also applicable to an organic EL display device in which the layered structure of the organic EL layer is reversed with the first electrode being a cathode electrode and the second electrode being an anode electrode.

Although the organic EL display device in which the electrode of the TFT connected to the first electrode serves as the drain electrode has been exemplified in each of the embodiments described above, the disclosure is also applicable to an organic EL display device in which the electrode of the TFT connected to the first electrode is referred to as the source electrode.

In each of the embodiments described above, the organic EL display device is exemplified as a display device. The disclosure can also be applied to a display device including a plurality of light-emitting elements driven by a current, for example, to a display device including quantum dot light-emitting diodes (QLEDs), which are a light-emitting element using a quantum dot-containing layer.

### Industrial Applicability

As described above, the disclosure is useful for a flexible display device.

1. A display device comprising:
a display panel including a display region where a plurality of subpixels are arranged, the display region including a first display region, a second display region provided adjacent to the first display region, and a third display region provided inside the second display region; and
an electronic component that is provided on one front face side of the display panel and overlaps with the third display region,
wherein the second display region is provided along an edge of the display panel, and
a density of the subpixels that can be turned on in the second display region other than the third display region is less than a density of the subpixels that can be turned on in the first display region and greater than a density of the subpixels that can be turned on in the third display region.

2. The display device according to claim 1,
wherein in the first display region, the subpixels that can be turned on are arranged in a matrix shape, and
in the second display region, the subpixels that cannot be turned on are arranged around the subpixels that can be turned on.

3. The display device according to claim 2,
wherein a boundary between the subpixels that can be turned on of the first display region and the subpixels that cannot be turned on of the second display region has an uneven shape in a plan view.

4. The display device according to claim 1,
wherein the display panel has a rectangular shape in a plan view, and
the second display region is provided along a side of the display panel.

5. The display device according to claim 1,
wherein the display panel includes a curved edge in a plan view, and the second display region is provided along the curved edge of the display panel.

6. The display device according to claim 1,
wherein the display panel has a rectangular shape in a plan view, and the second display region is provided along a corner of the display panel.

7. The display device according to claim 1,
wherein a plurality of the third display regions are provided inside the second display region.

8. The display device according to claim 2,
wherein the display panel includes
a base substrate,
a thin film transistor layer provided on the base substrate, the thin film transistor layer including a first flattening film, an inorganic insulating film, and a second flattening film layered sequentially in this order with a thin film transistor disposed on the first flattening film on a side of the base substrate for each subpixel that can be turned on,
a light-emitting element layer provided on the thin film transistor layer with a plurality of first electrodes, a plurality of light-emitting function layers, and a common second electrode are layered sequentially in this order corresponding to the plurality of subpixels that can be turned on, and
a sealing film provided on the light-emitting element layer,
wherein in the subpixels that can be turned on, the thin film transistor and the first electrodes are electrically connected to each other via a contact hole formed in the first flattening film, the inorganic insulating film, and the second flattening film, and
in a portion of the subpixels that cannot be turned on, a through-hole is formed in the inorganic insulating film.

9. The display device according to claim 8,
wherein more of the through-holes are formed on an edge side of the display panel of the second display region than on a side of the first display region of the second display region.

10. The display device according to claim 8,
wherein the through-hole is also formed outside of the display region on an edge side of the display panel.

11. The display device according to claim 8,
wherein each of the plurality of light-emitting function layers is an organic electroluminescence layer.

12. The display device according to claim 1,
wherein the electronic component is an imaging element.

13. The display device according to claim 1,
wherein the electronic component is an optical sensor.
